(19) United States
(12) Patent Application Publication
(10) Pub. No.: US 2023/0062967 A1
(43) Pub. Date: Mar. 2, 2023

(54) SEMICONDUCTOR DEVICE WITH CONTACTS HAVING DIFFERENT DIMENSIONS AND METHOD FOR FABRICATING THE SAME

(71) Applicant: NANYA TECHNOLOGY CORPORATION, NEW TAIPEI CITY (TW)

(72) Inventor: Tse-Yao HUANG, TAIPEI CITY (TW)

(21) Appl. No.: 17/462,309

(22) Filed: Aug. 31, 2021

(51) Int. Cl. H01L 21/74; H01L 21/768; H01L 21/3105; H01L 23/485

(52) U.S. Cl. CPC H01L 21/743; H01L 21/76843; H01L 21/76877; H01L 21/31056; H01L 23/485

(57) ABSTRACT

The present application discloses a semiconductor device and a method for fabricating the semiconductor device. The semiconductor device includes a substrate including a dense area and an open area; a dielectric structure positioned on the substrate; a landing pad positioned in the dielectric structure and above the dense area; a first contact positioned on the landing pad and in the dielectric structure; and a second contact positioned in the dielectric structure and on the open area of the substrate. A top surface of the first contact and a top surface of the second contact are substantially coplanar. A width of the first contact is less than the one half of a width of the second contact.

### TECHNICAL FIELD

The present disclosure relates to a semiconductor device and a method for fabricating the semiconductor device, and more particularly, to a semiconductor device with contacts having different dimensions and a method for fabricating the semiconductor device with the contacts having different dimensions.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a substrate including a dense area and an open area; a dielectric structure positioned on the substrate; a landing pad positioned in the dielectric structure and above the dense area; a first contact positioned on the landing pad and in the dielectric structure; and a second contact positioned in the dielectric structure and on the open area of the substrate. A top surface of the first contact and a top surface of the second contact are substantially coplanar. A width of the first contact is less than the one half of a width of the second contact.

In some embodiments, a depth of first contact is greater than two thirds of a depth of the second contact.

In some embodiments, a ratio of an aspect ratio of the first contact and an aspect ratio of the second contact is about 1.33:1.00.

Another aspect of the present disclosure provides a method for fabricating a semiconductor device including providing a substrate including a dense area and an open area; forming a dielectric structure on the substrate and forming a first hard mask layer on the dielectric structure; patterning the first hard mask layer to form a first mask opening above the dense area and a second mask opening above the open area; covering the open area with a first mask layer; forming a plurality of spacers on sidewalls of the first mask opening; performing a dense area etch process using the plurality of spacers and the first mask opening as pattern guides to form a first contact opening; removing the first mask layer and covering the dense area with a second mask layer; performing an open area etch process using the second mask opening as a pattern guide to form a second contact opening; and forming first contact in the first contact opening and a second contact in the second contact opening.

In some embodiments, forming the plurality of spacers on the sidewalls of the first mask opening includes: conformally forming a layer of spacer material on the first hard mask layer, on the first mask layer, and in the first mask opening; and performing a spacer etch process to turn the layer of spacer material into the plurality of spacers.

In some embodiments, the spacer material includes low temperature silicon.

In some embodiments, the first hard mask layer includes polycrystalline silicon.

In some embodiments, a width of the first contact opening is less than one half of a width of the second contact opening.

In some embodiments, the method for fabricating the semiconductor device includes forming a landing pad in the dielectric structure and above the dense area. A top surface of the landing pad is partially exposed through the first contact opening.

In some embodiments, a depth of the first contact opening is greater than two thirds of a depth of the second contact opening.

In some embodiments, an aspect ratio of the first contact opening is greater than an aspect ratio of the second contact opening.

In some embodiments, a ratio of an aspect ratio of the first contact opening and an aspect ratio of the second contact opening is about 1.33:1.00.

In some embodiments, an oxygen concentration of the dense area etch process is greater than an oxygen concentration of the open area etch process.

In some embodiments, a bias power of the dense area etch process is greater than a bias power of the open area etch process.

In some embodiments, a process pressure of the dense area etch process is less than a process pressure of the open area etch process.

In some embodiments, a width of the first mask opening and a width of the second mask opening are substantially the same.

In some embodiments, a thickness of the plurality of spacers is greater than or equal to one fourth of a width of the second contact opening.

In some embodiments, forming the first contact in the first contact opening and forming the second contact in the second contact opening including: forming a layer of conductive material to completely fill the first contact opening and the second contact opening; and performing a planarization process until a top surface of the dielectric structure is exposed to turn the layer of conductive material into the first contact and the second contact.

In some embodiments, the dense area and the open area are adjacent to each other.

In some embodiments, a top surface of the substrate is partially exposed through the second contact opening.

Due to the design of employing the spacers in the dense area etch process in the fabrication of the semiconductor device of the present disclosure, the dimension of the first contacts may be easily reduced so as to meet the tighter design rule of the dense area. Furthermore, the process complexity of fabrication of the semiconductor device may be reduced as comparing to using smaller dimension of photolithography mask which may suffer serious shifting issues. In addition, the dimension of the second contact for the looser design rule of the open area may be concurrently met by using the open area process. As a result, the yield of the semiconductor device may be accordingly improved.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in a flowchart diagram form, a method for fabricating a semiconductor device in accordance with one embodiment of the present disclosure;

FIGS. 2 to 16 illustrate, in schematic cross-sectional view diagrams, a flow for fabricating the semiconductor device in accordance with one embodiment of the present disclosure;

FIGS. 17 to 19 are schematic cross-sectional view diagrams illustrating part of a flow for fabricating a semiconductor device in accordance with another embodiment of the present disclosure;

FIGS. 20 to 22 are schematic cross-sectional view diagrams illustrating part of a flow for fabricating a semiconductor device in accordance with another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the direction Z, and below (or down) corresponds to the opposite direction of the arrow of the direction Z.

It should be noted that, in the description of the present disclosure, a surface of an element (or a feature) located at the highest vertical level along the dimension Z is referred to as a top surface of the element (or the feature). A surface of an element (or a feature) located at the lowest vertical level along the dimension Z is referred to as a bottom surface of the element (or the feature).

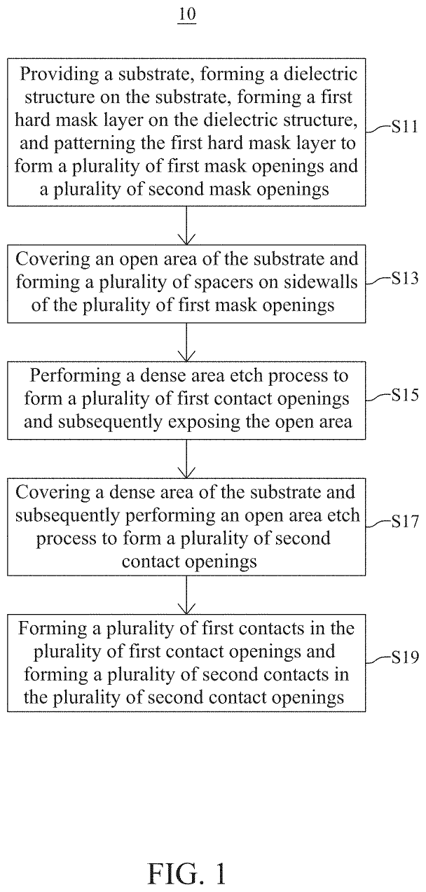

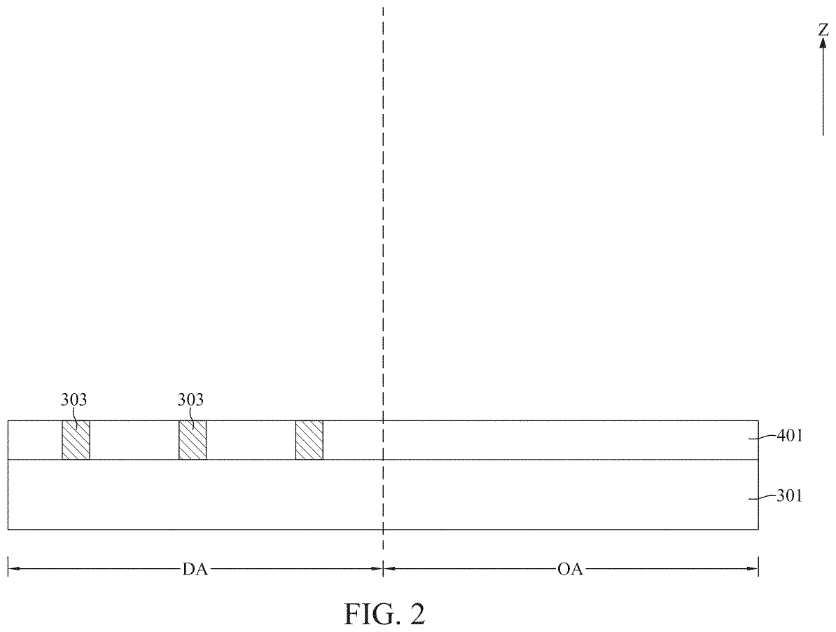

FIG. 1 illustrates, in a flowchart diagram form, a method 10 for fabricating a semiconductor device 1A in accordance with one embodiment of the present disclosure. FIGS. 2 to 16 illustrate, in schematic cross-sectional view diagrams, a flow for fabricating the semiconductor device 1A in accordance with one embodiment of the present disclosure.

With reference to FIGS. 1 to 6, at step S11, a substrate 301 may be provided, a dielectric structure 400 may be formed on the substrate 301, a first hard mask layer 501 may be formed on the dielectric structure 400, and the first hard mask layer 501 may be patterned to form a plurality of first mask openings 501D and a plurality of second mask openings 501O.

With reference to FIG. 2, the substrate 301 may include a dense area DA and an open area OA. In some embodiments, the substrate 301 may be a single die. The dense area DA may be located at the center region of the die. The open area OA may be located at the peripheral region of the die. In some embodiments, the dense area DA and the open area OA may be adjacent to each other. In some embodiments, the dense area DA and the open area OA may be separated from each other. In some embodiments, the substrate 301 may be a semiconductor wafer.

It should be noted that the dense area DA may comprise a portion of the substrate 301 and a space above the portion of the substrate 301. Describing an element as being formed on the dense area DA means that the element is formed on a top surface of the portion of the substrate 301. Describing an element as being formed in the dense area DA means that the element is formed in the portion of the substrate 301; however, a top surface of the element may be even with the top surface of the portion of the substrate 301. Describing an element as being formed above the dense area DA means that the element is formed above the top surface of the portion of the substrate 301. Accordingly, the open area OA may comprise another portion of the substrate 301 and a space above the other portion of the substrate 301.

In some embodiments, the substrate 301 may include a bulk semiconductor substrate that is composed at least one semiconductor material. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; a non-semiconductor material, such as soda-lime glass, fused silica, fused quartz, calcium fluoride; other suitable materials; or combinations thereof.

In some embodiments, the substrate 301 may include a semiconductor-on-insulator structure which is consisted of, from bottom to top, a handle substrate, an insulator layer, and a topmost semiconductor material layer. The handle substrate and the topmost semiconductor material layer may be formed of a same material as the bulk semiconductor substrate aforementioned. The insulator layer may be a crystalline or non-crystalline dielectric material such as an oxide and/or nitride. For example, the insulator layer may be a dielectric oxide such as silicon oxide. For another example, the insulator layer may be a dielectric nitride such as silicon nitride or boron nitride. For yet another example, the insulator layer may include a stack of a dielectric oxide and a dielectric nitride such as a stack of, in any order, silicon oxide and silicon nitride or boron nitride. The insulator layer may have a thickness between about 10 nm and about 200 nm.

It should be noted that, the term “about” modifying the quantity of an ingredient, component, or reactant of the present disclosure employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value.

In some embodiments, the substrate 301 may include dielectrics, insulating layers, or conductive features (not shown) formed on the bulk semiconductor substrate or the topmost semiconductor material layer. The dielectrics or the insulating layers may be formed of, for example, silicon oxide, borophosphosilicate glass, undoped silicate glass, fluorinated silicate glass, low-k dielectric materials, the like, or a combination thereof. Each of the dielectrics or each of the insulating layers may have a thickness between about 0.5 micrometer and about 3.0 micrometer. The low-k dielectric materials may have a dielectric constant less than 3.0 or even less than 2.5. The conductive features may be conductive lines, conductive vias, conductive contacts, or the like.

In some embodiments, device elements (not shown) may be disposed in the substrate 301. The device elements may be, for example, bipolar junction transistors, metal-oxide-semiconductor field effect transistors, diodes, system large-scale integration, flash memories, dynamic random-access memories, static random-access memories, electrically erasable programmable read-only memories, image sensors, micro-electro-mechanical system, active devices, or passive devices. The device elements may be electrically insulated from neighboring device elements by insulating structures such as shallow trench isolation.

In some embodiments, depending on the specific stage of processing, the substrate 301 may correspond to a silicon substrate, or other material layer that has been formed on the substrate.

With reference to FIG. 2, a bottom insulation layer 401 may be blanket formed on the substrate 301. The bottom insulation layer 401 may be formed of, for example, silicon oxide, borophosphosilicate glass, undoped silicate glass, fluorinated silicate glass, low-k dielectric materials, the like, or a combination thereof. The bottom insulation layer 401 may be formed by, for example, chemical vapor deposition, plasma-enhanced chemical vapor deposition, or other applicable deposition process.

With reference to FIG. 2, a plurality of bottom conductive contacts 303 may be formed in the bottom insulation layer 401 and above the dense area DA. The plurality of bottom conductive contacts 303 may be formed by a photolithography process with a subsequent etch process and a subsequent deposition process. The plurality of bottom conductive contacts 303 may be formed of, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. The plurality of bottom conductive contacts 303 may be electrically coupled to the device elements of the substrate 301.

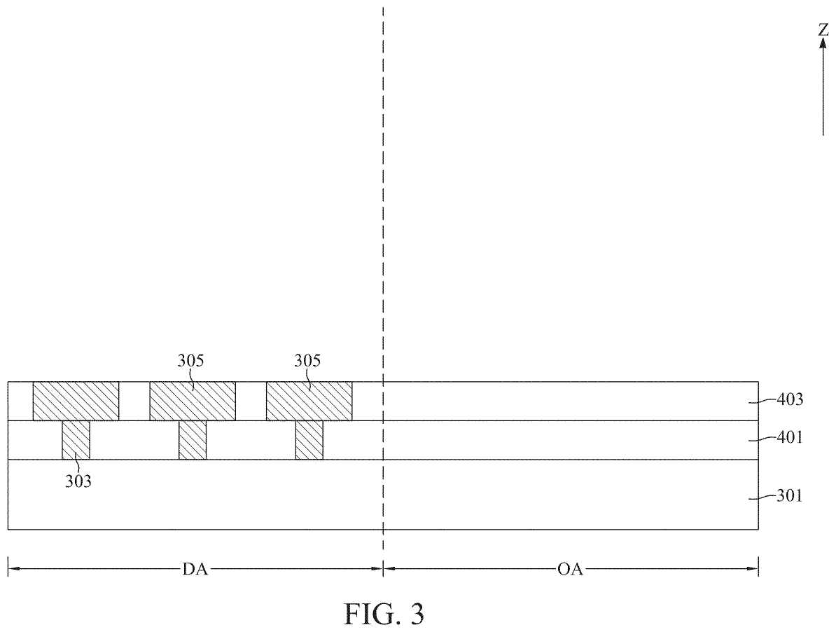

With reference to FIG. 3, a middle insulation layer 403 may be blanket formed on the bottom insulation layer 401. In some embodiments, the middle insulation layer 403 may be formed of a same material as the bottom insulation layer 401. In some embodiments, the middle insulation layer 403 may be formed of, for example, silicon oxide, borophosphosilicate glass, undoped silicate glass, fluorinated silicate glass, low-k dielectric materials, the like, or a combination thereof. The middle insulation layer 403 may be formed by, for example, chemical vapor deposition, plasma-enhanced chemical vapor deposition, or other applicable deposition process.

With reference to FIG. 3, a plurality of landing pads 305 may be formed in the middle insulation layer 403 and above the dense area DA. The plurality of landing pads 305 may be formed by a photolithography process with a subsequent etch process and a subsequent deposition process. The plurality of landing pads 305 may be formed of, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. The plurality of landing pads 305 may be electrically coupled to plurality of bottom conductive contacts 303, respectively and correspondingly.

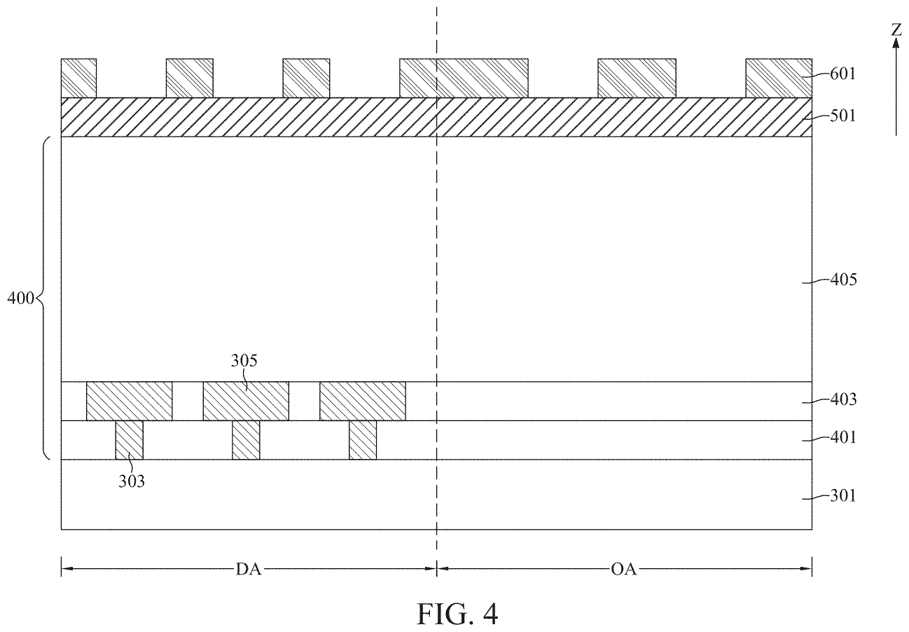

With reference to FIG. 4, a top insulation layer 405 may be formed on the middle insulation layer 403. In some embodiments, the top insulation layer 405 may be formed of a same material as the bottom insulation layer 401. In some embodiments, the top insulation layer 405 may be formed of, for example, silicon oxide, borophosphosilicate glass, undoped silicate glass, fluorinated silicate glass, low-k dielectric materials, the like, or a combination thereof. The top insulation layer 405 may be formed by, for example, chemical vapor deposition, plasma-enhanced chemical vapor deposition, or other applicable deposition process.

The bottom insulation layer 401, the middle insulation layer 403, and the top insulation layer 405 together configure the dielectric structure 400.

With reference to FIG. 4, the first hard mask layer 501 may be formed on the top insulation layer 405. In some embodiments, the first hard mask layer 501 may be formed of, for example, polycrystalline silicon and may be formed by, for example, chemical vapor deposition, plasma-enhanced chemical vapor deposition, or other applicable deposition process.

Alternatively, in some embodiments, the first hard mask layer 501 may be formed of, for example, a carbon film. The terms “carbon film” is used herein to describe materials whose mass is primarily carbon, whose structure is defined primarily by carbon atoms, or whose physical and chemical properties are dominated by its carbon content. The term “carbon film” is meant to exclude materials that are simply mixtures or compounds that include carbon, for example dielectric materials such as carbon-doped silicon oxynitride, carbon-doped silicon oxide or carbon-doped polysilicon.

Alternatively, in some embodiments, the first hard mask layer 501 may be composed of carbon and hydrogen. In some embodiments, the first hard mask layer 501 may be composed of carbon, hydrogen, and oxygen. In some embodiments, the first hard mask layer 501 may be composed of carbon, hydrogen, and fluorine.

Alternatively, in some embodiments, the first hard mask layer 501 may be formed of a material identified in the trade as APF (product model, manufactured by AMAT Corp.), a material identified in the trade as SiLK (product model, manufactured by Dow Chemical Co.), a material identified in the trade as NCP (product model, manufactured by ASM Corp.), a material identified in the trade as AHM (product model, manufactured by Novellous Corp.), or similar such materials.

In some embodiments, the first hard mask layer 501 may be formed by a high density plasma chemical vapor deposition process. The high density plasma may be generated using inductively coupled radio frequency (RF) power in a range between about 500 watts and about 4000 watts. In some embodiments, the high density plasma may be generated using a capacitively coupled RF power in a range between about 500 watts and about 4000 watts. The source of carbon may be methane, ethane, ethyne, benzene, or a combination thereof. The flow rate of the source of carbon may be between about 50 standard cubic feet per minute (sccm) and about 150 sccm. The source of carbon may provide polymerization of carbon to form carbon-carbon chains. An inert gas such as argon, neon, or helium may be used as carrier gas to carry the source of carbon. The flow rate of the carrier gas may be between about 10 sccm and about 150 sccm. The process pressure of the high density plasma chemical vapor deposition process may be about 5 millitorr and about 20 millitorr. The process temperature of the high density plasma chemical vapor deposition process may be between about 240° C. and about 340° C.

In some embodiments, the first hard mask layer 501 may be formed with fluorine doping by adding a source of fluorine during the high density plasma chemical vapor deposition process. The source of fluorine may be, for example, octafluorocyclobutane, tetrafluoromethane, hexafluoroethane, octafluoropropane, trifluoromethane, hexafluorobenzene, or a combination thereof. The flow rate of the source of fluorine may be between slightly greater 0 and about 150 sccm. The flow rate ratio of the source of fluorine to the source of carbon is important for the doping level and the thermal stability of the carbon hard mask layer 105. For an unbiased process situation, the flow rate ratio of the source of fluorine to the source of carbon may be between about 0.2 and about 2. For a biased process situation, the flow rate ratio of the source of fluorine to the source of carbon may be between about 0.7 and about 1.3.

In some embodiments, an annealing process may be performed after the high density plasma chemical vapor deposition process to enhance the thermal stability of the first hard mask layer 501. The annealing process may be carried out in vacuum, or in an inert atmosphere composed of gasses such as argon or nitrogen, at a temperature between about 300° C. and about 450° C. for approximately 30 minutes.

The thickness and uniformity of the first hard mask layer 501 formed by the high density plasma chemical vapor deposition process may be well controlled. For example, the standard deviation of the thickness of the first hard mask layer 501 may be less than 4%. In addition, the first hard mask layer 501 formed by the high density plasma chemical vapor deposition process may be thermally stable at elevated temperatures up to approximately 400° C. Thermal stability means that the first hard mask layer 501 will not suffer from weight loss, deformation or chemical reactions when exposed to etch environments at temperatures between about 200° C. and about 400° C. The thermal stability of the first hard mask layer 501 at elevated temperatures, will allow for its use as a mask for etch operations that are performed at temperatures higher than 200° C. Furthermore, the etch resistance property of the first hard mask layer 501 may be tuned by adjusting the doping level of fluorine. The etch resistive property of the first hard mask layer 501 may be decreased with higher doping level of fluorine.

Alternatively, in some embodiments, the first hard mask layer 501 may be a carbon film. The carbon film may be deposited by a process including introducing a processing gas mixture, consisting of one or more hydrocarbon compounds, into a processing chamber. The hydrocarbon compound has a formula CₓH_{y}, where ₓ has a range of between 2 and 4 and y has a range of between 2 and 10. The hydrocarbon compounds may be, for example, propylene (C₃H₆), propyne (C₃H₄), propane (C₃H₈), butane (C₄H₁₀), butylene (C₄H₈), butadiene (C₄H₆), or acetylene (C₂H₂), or a combination thereof.

In some embodiments, the carbon film may be deposited from the processing gas mixture by maintaining a substrate temperature between about 100° C. and about 700° C.; specifically, between about 350° C. and about 550° C. In some embodiments, the carbon film may be deposited from the processing gas mixture by maintaining a chamber pressure between about 1 Torr and about 20 Torr. In some embodiments, the carbon film may be deposited from the processing gas mixture by introducing the hydrocarbon gas, and any inert, or reactive gases respectively, at a flow rate between about 50 sccm and about 2000 sccm.

In some embodiments, the processing gas mixture may further include an inert gas, such as argon. However, other inert gases, such as nitrogen or other noble gases, such as helium may also be used. Inert gases may be used to control the density and deposition rate of the carbon film. Additionally, a variety of gases may be added to the processing gas mixture to modify properties of the carbon film. The gases may be reactive gases, such as hydrogen, ammonia, a mixture of hydrogen and nitrogen, or a combination thereof. The addition of hydrogen or ammonia may be used to control the hydrogen ratio of the carbon film to control layer properties, such as etch selectivity, chemical mechanical polishing resistance property, and reflectivity. In some embodiments, a mixture of reactive gases and inert gases may be added to the processing gas mixture to deposit the carbon film.

The carbon film may include carbon and hydrogen atoms, which may be an adjustable carbon:hydrogen ratio that ranges from about 10% hydrogen to about 60% hydrogen. Controlling the hydrogen ratio of the carbon film may tune the respective etch resistance property and chemical mechanical polishing resistance property. As the hydrogen content decreases, the etch resistance property, and thus the etch selectivity, of the carbon film increases. The reduced rate of removal of the carbon film may make the carbon film suitable for being a mask layer when performing an etch process to transfer desire pattern onto the underlying layers.

With reference to FIG. 4, a top mask layer 601 may be formed on the first hard mask layer 501. The top mask layer 601 may be, for example, a photoresist layer. The top mask layer 601 may have a pattern of the plurality of first mask openings 501D and the plurality of second mask openings 501O.

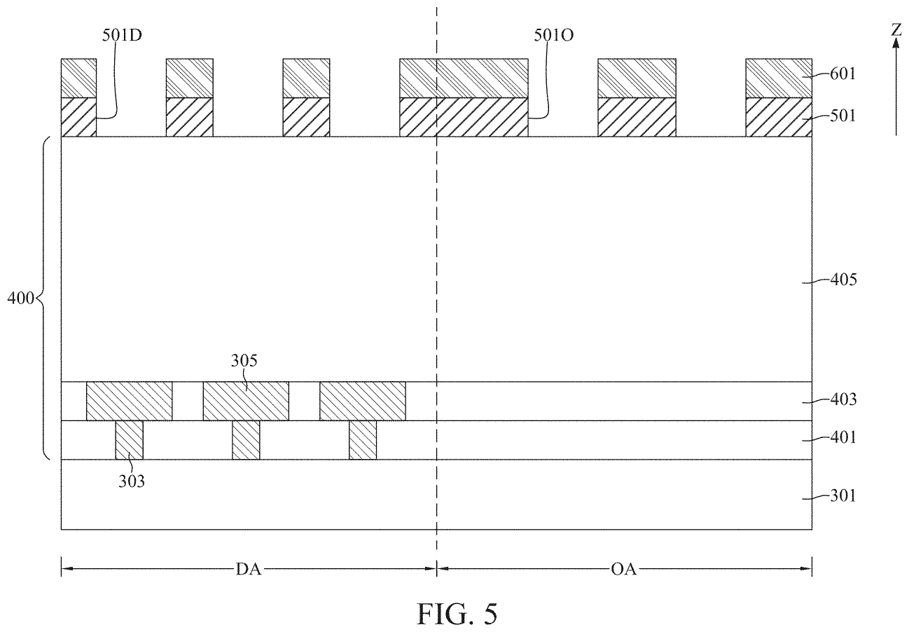

With reference to FIG. 5, a hard mask etch process may be performed to transfer the pattern of the top mask layer 601 onto the first hard mask layer 501. In some embodiments, the hard mask etch process may conduct by fluorine-containing plasma using trifluoromethane as plasma source. In some embodiments, the hard mask etch process may conduct by oxygen-containing plasma. In some embodiments, during the hard mask etch process, the etch rate of the first hard mask layer 501 may be greater than the etch rate of the dielectric structure 400. For example, the etch rate ratio of the first hard mask layer 501 to the dielectric structure 400 may be between about 20:1 and about 2:1. For another example, the etch rate ratio of the first hard mask layer 501 to the dielectric structure 400 may be between about 10:1 and about 3:1. For yet another example, the etch rate ratio of the first hard mask layer 501 to the dielectric structure 400 may be between about 5:1 and about 3:1.

After the hard mask etch process, the plurality of first mask openings 501D may be formed along the first hard mask layer 501 and may be above the dense area DA. The plurality of second mask openings 501O may be formed along the first hard mask layer 501 and may be above the open area OA.

For brevity, clarity, and convenience of description, only one first mask opening 501D and one second mask opening 501O is described. In some embodiments, the width W1 of the first mask opening 501D and the width W2 of the second mask opening 501O may be substantially the same. In some embodiments, the width W1 of the first mask opening 501D may be less than the width W2 of second mask opening 501O.

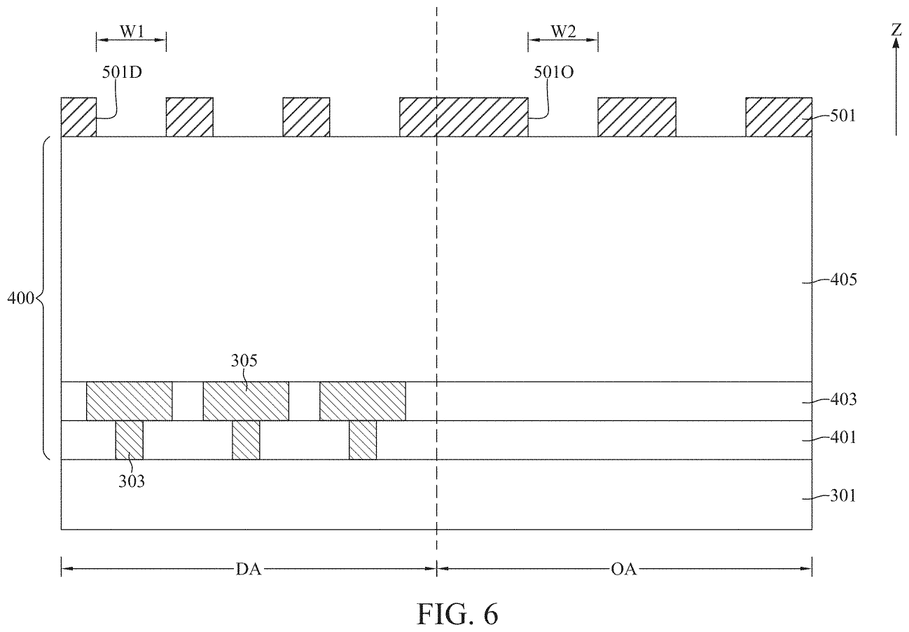

With reference to FIG. 6, after the formation of the plurality of first mask openings 501D and the plurality of second mask openings 501O, the top mask layer 601 may be removed by, for example, ashing or other applicable process.

With reference to FIG. 1 and FIGS. 7 to 9, at step S13, the open area OA may be covered and a plurality of spacers 503 may be formed on sidewalls of the plurality of first mask openings 501D.

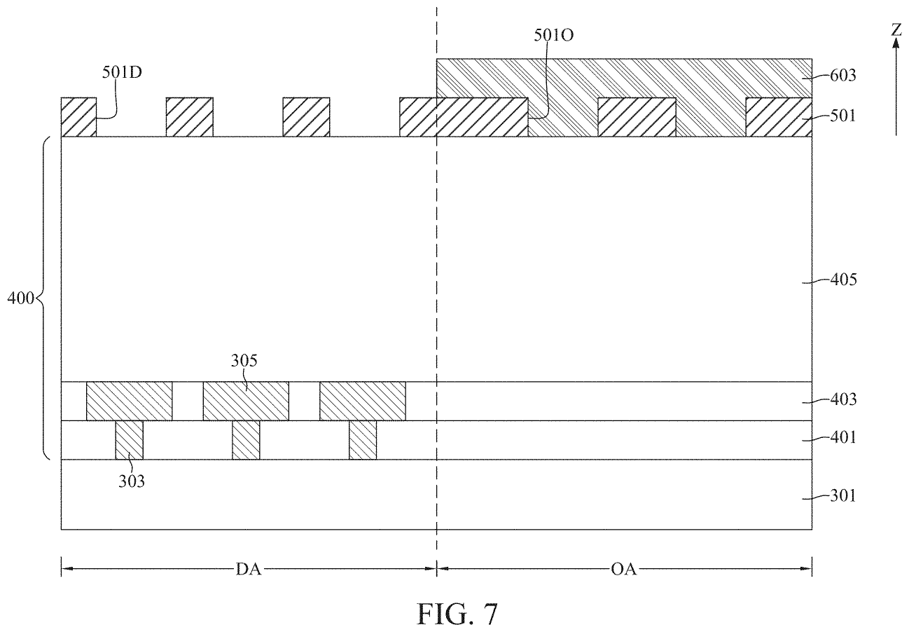

With reference to FIG. 7, a first mask layer 603 may be formed to cover the open area OA and fill the plurality of second mask openings 501O. The first mask layer 603 may be a photoresist layer.

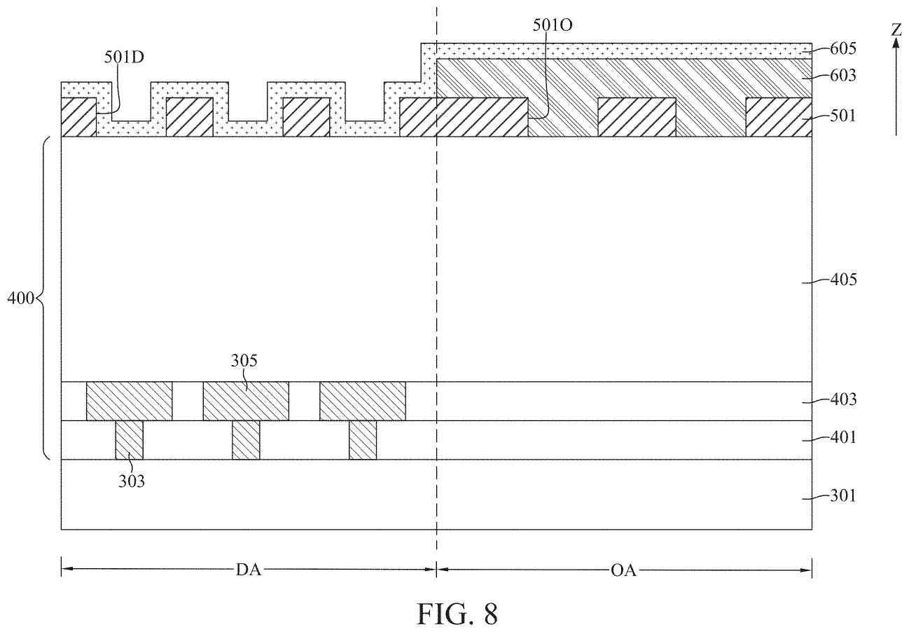

With reference to FIG. 8, a layer of spacer material 605 may be conformally formed on the top surface of the first hard mask layer 501, the top surface and the sidewall of the first mask layer 603, and the bottom surfaces and the sidewalls of the plurality of first mask openings 501D. In some embodiments, the spacer material 605 may be, for example, a material having etch selectivity to the top insulation layer 405 or a material having etch selectivity to the top insulation layer 405 and the first hard mask layer 501. In some embodiments, the spacer material 605 may be, for example, low temperature silicon.

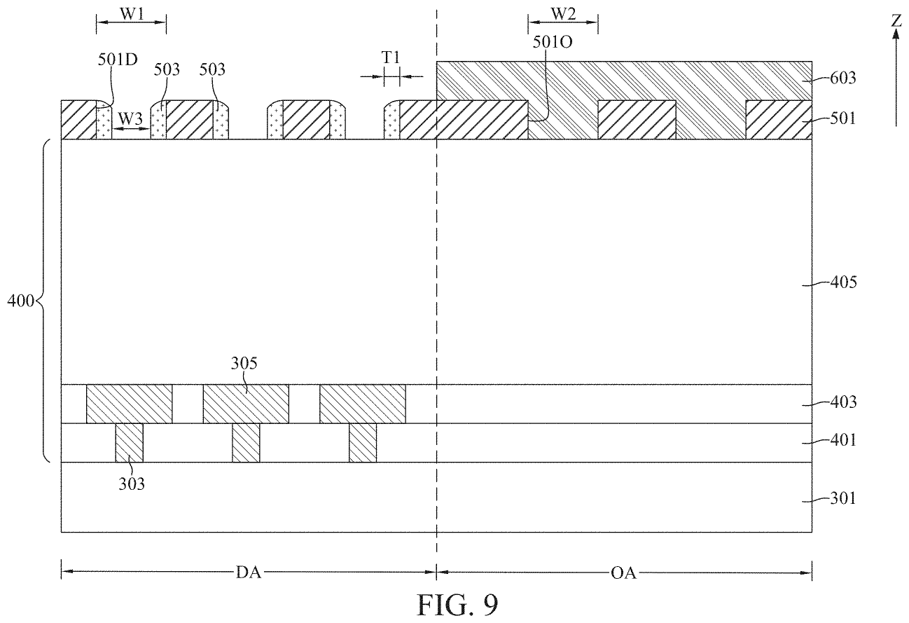

With reference to FIG. 9, a spacer etch process may be performed to remove portions of the layer of spacer material 605 formed on the top surface and the sidewall of the first mask layer 603, on the top surface of the first hard mask layer 501, and on the bottoms of the plurality of first mask openings 501D. The spacer etch process may be an anisotropic etch process. The etch rate ratio of the layer of spacer material 605 to the top insulation layer 405 may be between about 100:1 and about 1.05:1, between about 15:1 and about 2:1, or between about 10:1 and about 2:1 during the spacer etch process. After the spacer etch process, the remained spacer material 605 may be regarded as the plurality of spacers 503.

It should be noted that the plurality of spacers 503 may trim the plurality of first mask openings 501D. The distance W3 between an adjacent pair of the plurality of spacers 503 in the corresponding first mask opening 501D may be less than the width W1 of the first mask opening 501D.

For brevity, clarity, and convenience of description, only one spacer 503 is described. In some embodiments, the thickness T1 of the spacer 503 may be greater than or equal to one fourth of the width W1 of the first mask opening 501D. In some embodiments, the thickness T1 of the spacer 503 may be greater than or equal to one fourth of the width W2 of the second mask opening 501O.

With reference to FIGS. 1, 10, and 11, at step S15, a dense area etch process may be performed to form a plurality of first contact openings 101O and the open area OA may be subsequently exposed.

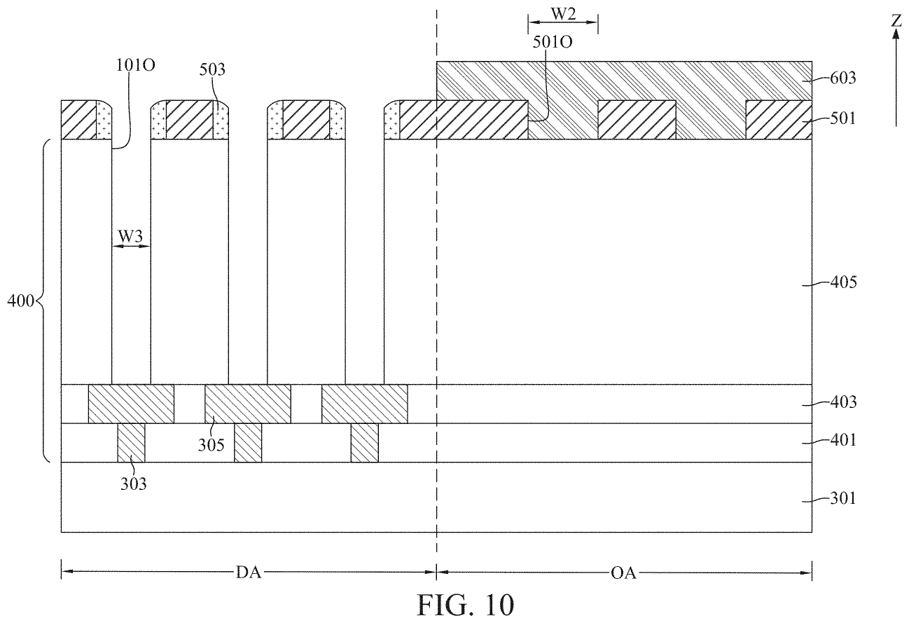

With reference to FIG. 10, the dense area etch process may use the first hard mask layer 501 and the plurality of spacers 503 as pattern guides to remove portions of the top insulation layer 405 to form the plurality of first contact openings 101O along the top insulation layer 405. The dimension (e.g., width) of the first contact opening 101O may be determined by the first mask opening 501D and the spacers 503. That is, the first contact opening 101O may have the width W3. In some embodiments, the width W3 of the first contact opening 101O may be less than the width W2 of the second mask opening 501O. In some embodiments, the width W3 of the first contact opening 101O may be less than one half of the width W2 of the second mask opening 501O.

It should be noted that, in the description of the present disclosure, a “height” or a “depth” refers to a vertical size of an element (e.g., a layer, plug, trench, hole, opening, etc.) in a cross-sectional perspective measured from a top surface to a bottom surface of the element; a “width” refers to a size of an element (e.g., a layer, plug, trench, hole, opening, etc.) in a cross-sectional perspective measured from a side surface to an opposite surface of the element. The term “thickness” may substitute for “width” and/or “height”/“depth” where indicated.

In some embodiments, the dense area etch process may be conducted in any suitable plasma processing apparatus, for example, a reactive ion etching apparatus. The reactive ion etching apparatus may contain an anode and cathode within a vacuum chamber. The cathode is typically in the form of a pedestal for supporting a semiconductor wafer within the chamber, while the anode is typically formed of the walls and top of the chamber. To process a wafer, a plasma source gas is pumped into the vacuum chamber and the anode and cathode are driven by a single sinusoidal frequency source to excite the plasma source gas into a plasma. The single frequency is typically 13.56 MHz, although frequencies from 100 kHz to 2.45 GHz are often used, with the occasional use of other frequencies. The RF power excites the plasma source gas, producing a plasma within the chamber proximate the semiconductor wafer being processed. The etching chemistry used in the dense area etch process by the reactive ion etching apparatus is preferably based on a plasma source gas that contains oxygen.

In some embodiments, the plasma processing apparatus may also be a magnetically enhanced reactive ion etch apparatus. Such an apparatus is typically provided with one or more magnets or magnetic coils that magnetically control the plasma to facilitate a more uniform dense area etch process.

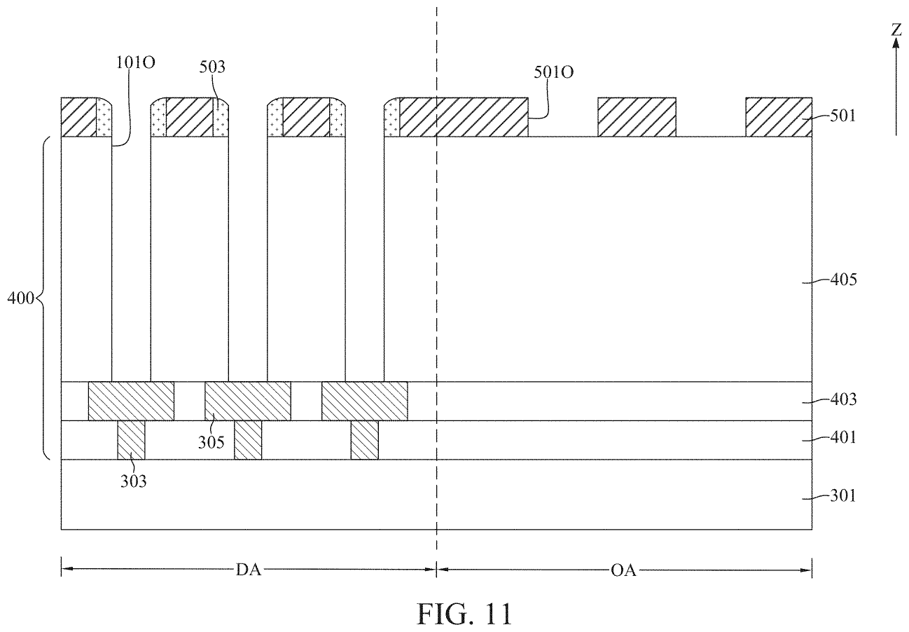

With reference to FIG. 11, after the formation of the plurality of first contact openings 101O, the first mask layer 603 may be removed by, for example, ashing. Portions of the top surfaces of the plurality of landing pads 305 may be exposed through the plurality of first contact openings 101O, respectively and correspondingly.

With reference to FIG. 1 and FIGS. 12 to 14, at step S17, the dense area DA may be covered, and an open area etch process may be subsequently performed to form a plurality of second contact openings 201O.

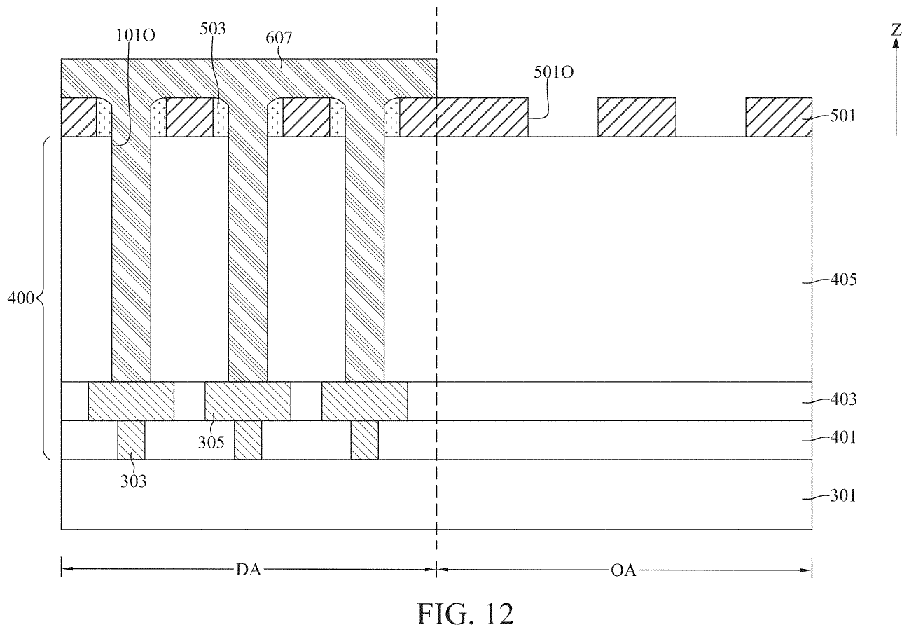

With reference to FIG. 12, a second mask layer 607 may be formed to cover the dense area DA and fill the plurality of first contact openings 101O. In some embodiments, the plurality of first contact openings 101O may be completely filled by the second mask layer 607. In some embodiments, the plurality of first contact openings 101O may be partially filled by the second mask layer 607. In some embodiments, the second mask layer 607 may be a photoresist layer.

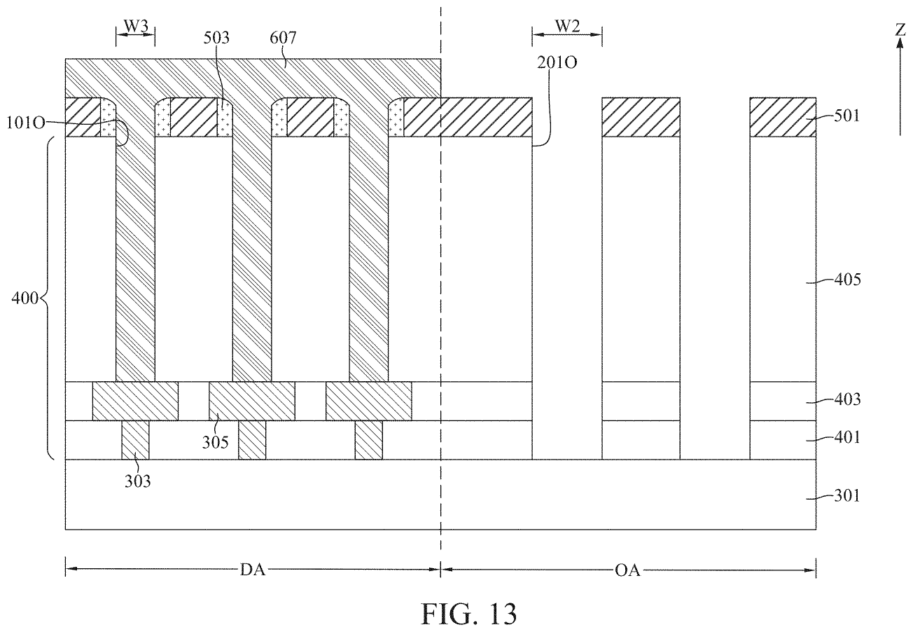

With reference to FIG. 13, the open area etch process may use the first hard mask layer 501 as a pattern guide to remove portions of the top insulation layer 405 to form the plurality of second contact openings 201O along the top insulation layer 405, the middle insulation layer 403, and the bottom insulation layer 401. The dimension (e.g., width) of the second contact opening 201O may be determined by the second mask opening 501O. That is, the second contact opening 201O may have the width W2. In some embodiments, the width W3 of the first contact opening 101O may be less than the width W2 of the second contact opening 201O. In some embodiments, the width W3 of the first contact opening 101O may be less than one half of the width W2 of the second contact opening 201O.

In some embodiments, the oxygen concentration of the open area etch process may be less than the oxygen concentration of the dense area etch process. In some embodiments, the bias power of the open area etch process may be less than the bias power of the dense area etch process. In some embodiments, the process pressure of the open area etch process may be less than the process pressure of the dense area etch process.

In some embodiments, the open area etch process may be conducted in any suitable plasma processing apparatus, for example, a reactive ion etching apparatus. The reactive ion etching apparatus may contain an anode and cathode within a vacuum chamber. The cathode is typically in the form of a pedestal for supporting a semiconductor wafer within the chamber, while the anode is typically formed of the walls and top of the chamber. To process a wafer, a plasma source gas is pumped into the vacuum chamber and the anode and cathode are driven by a single sinusoidal frequency source to excite the plasma source gas into a plasma. The single frequency is typically 13.56 MHz, although frequencies from 100 kHz to 2.45 GHz are often used, with the occasional use of other frequencies. The RF power excites the plasma source gas, producing a plasma within the chamber proximate the semiconductor wafer being processed. The etching chemistry used in the open area etch process by the reactive ion etching apparatus is preferably based on a plasma source gas that contains oxygen.

In some embodiments, the plasma processing apparatus may also be a magnetically enhanced reactive ion etch apparatus. Such an apparatus is typically provided with one or more magnets or magnetic coils that magnetically control the plasma to facilitate a more uniform dense area etch process.

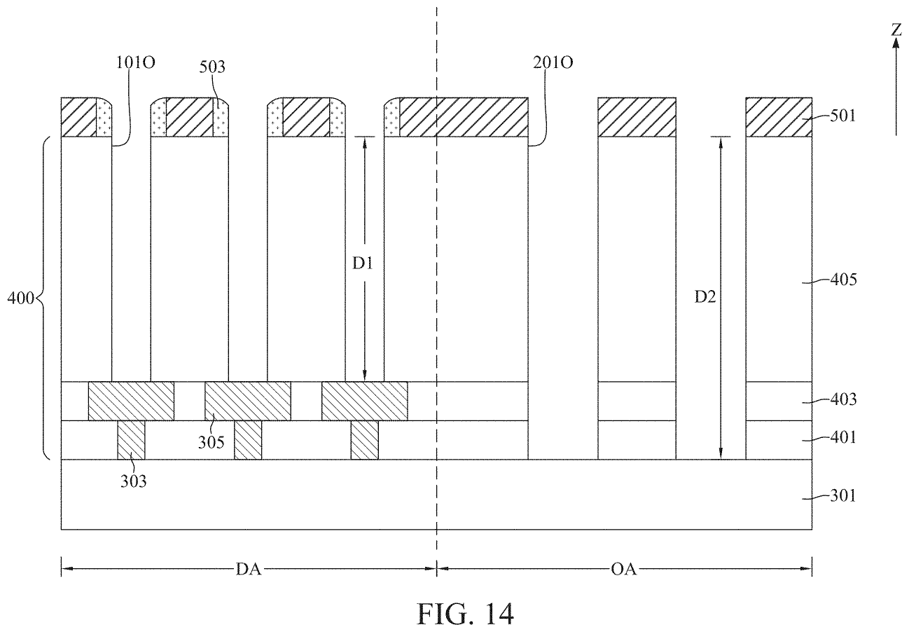

With reference to FIG. 14, after the formation of the plurality of second contact openings 201O. The second mask layer 607 may be removed by, for example, ashing. In some embodiments, the depth D1 of the first contact opening 101O may be less than the depth D2 of the second contact opening 201O. In some embodiments, the depth D1 of the first contact opening 101O may be greater than two thirds of the depth D2 of the second contact opening 201O. In some embodiments, the ratio of the aspect ratio of the first contact opening 101O to the aspect ratio of the second contact opening 201O may be about 1.33:1.

With reference to FIGS. 1, 15, and 16, at step S19, a plurality of first contacts 101 may be formed in the plurality of first contact openings 101O and a plurality of second contacts 201 may be formed in the plurality of second contact openings 201O.

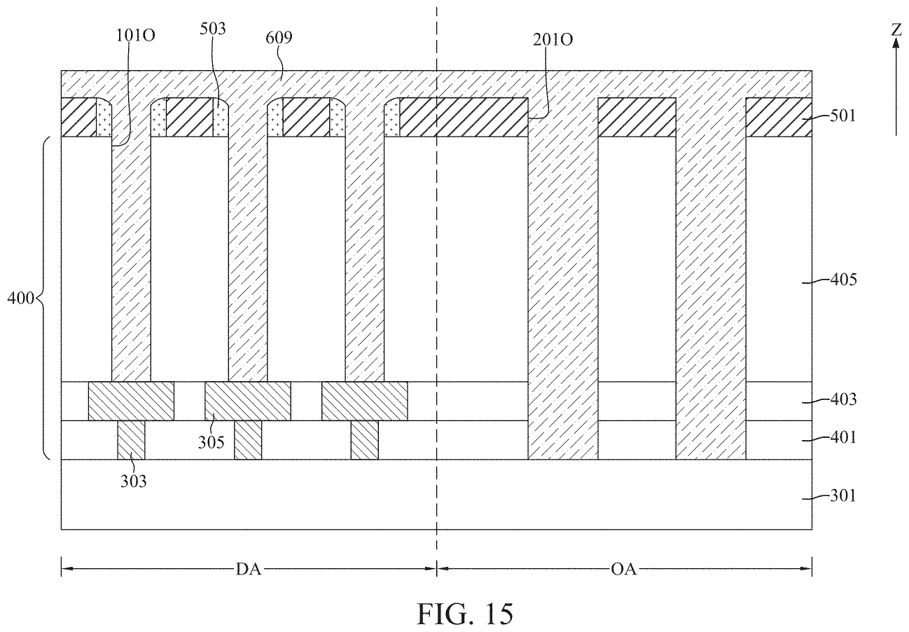

With reference to FIG. 15, a layer of conductive material 609 may be formed to fill the plurality of first contact openings 101O and the plurality of second contact openings 201O, and cover the first hard mask layer 501 and the plurality of spacers 503. The conductive material 609 may be, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. The layer of conductive material 609 may be formed by, for example, chemical vapor deposition, sputtering, electroplating, or other applicable deposition process.

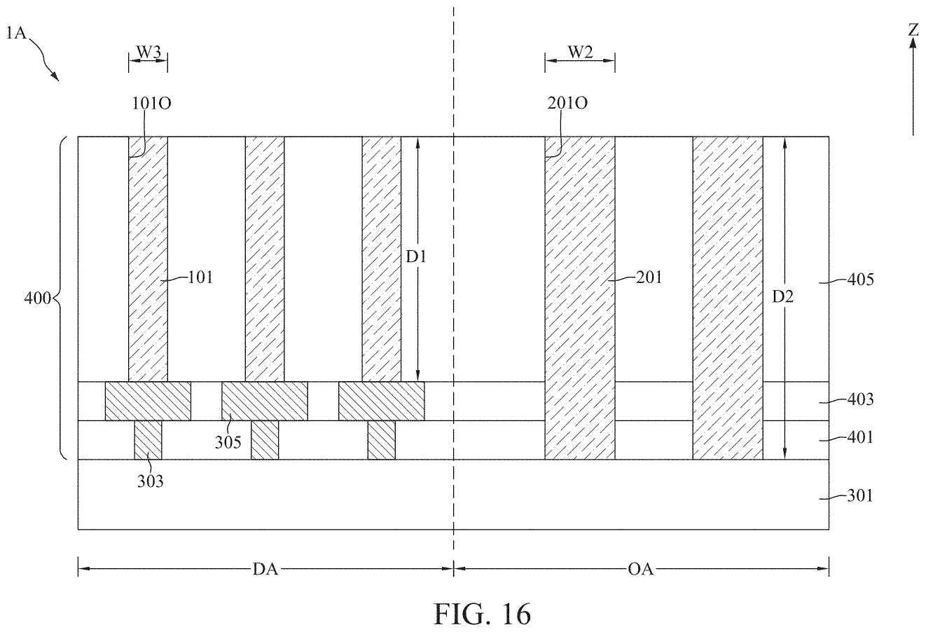

With reference to FIG. 16, a planarization process, such as chemical mechanical polishing, may be performed until the top surface of the top insulation layer 405 is exposed to remove excess material, provide a substantially flat surface for subsequent processing steps, and concurrently turn the layer of conductive material 609 into the plurality of first contacts 101 in the plurality of first contact openings 101O and the plurality of second contacts 201 in the plurality of second contact openings 201O.

For brevity, clarity, and convenience of description, only one first contact 101 and second contact 201 are described.

In some embodiments, the dimension (e.g., width and depth) of the first contact 101 and the second contact 201 may be determined by the first contact opening 101O and the second contact opening 201O, respectively and correspondingly. That is, the first contact 101 may have the width W3 and the depth D1; and the second contact 201 may have the width W2 and the depth D2. In some embodiments, the width W3 of the first contact 101 may be less than the width W2 of the second contact 201. In some embodiments, the width W3 of the first contact 101 may be less than one half of the width W2 of the second contact 201. In some embodiments, the depth D1 of the first contact 101 may be less than the depth D2 of the second contact 201. In some embodiments, the depth D1 of the first contact 101 may be greater than two thirds of the depth D2 of the second contact 201. In some embodiments, the ratio of the aspect ratio of the first contact 101 to the aspect ratio of the second contact 201 may be about 1.33:1.

In the description of present disclosure, the dense area DA may have an element density greater than that of the open area OA. The element density may be a value defined by the elements (e.g., transistors or contacts) formed in the dense area DA or the open area OA divided by surface areas of the dense area DA or the open area OA from a top-view perspective. From a cross-sectional perspective, a greater density may mean a smaller horizontal distance between adjacent elements. With reference to FIG. 16, more first contact 101 are shown in the dense area DA that of the second contact 201 shown in the open area OA to emphasize that the element density difference between the dense area DA and the open area OA. Numbers of the first contacts 101 or the second contacts 201 are illustrative only.

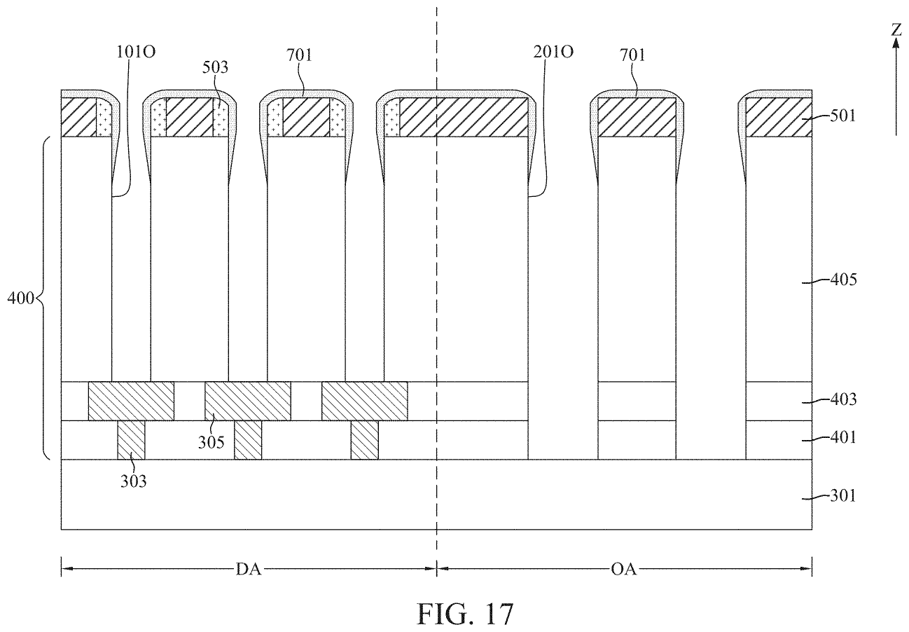

FIGS. 17 to 19 are schematic cross-sectional view diagrams illustrating part of a flow for fabricating a semiconductor device 1B in accordance with another embodiment of the present disclosure.

With reference to FIG. 17, an intermediate semiconductor device may be fabricated with a procedure similar to that illustrated in FIGS. 2 to 14, and descriptions thereof are not repeated herein. A plurality of assistance layers 701 may be formed to cover upper portions of the plurality of first contact openings 101O and the plurality of second contact openings 201O, respectively and correspondingly. The plurality of assistance layers 701 may be formed by a deposition process such as an atomic layer deposition precisely controlling an amount of a first precursor of the atomic layer deposition.

Generally, the precursors of the atomic layer deposition are separated during the reaction. The first precursor is passed over the substrate producing a monolayer on the substrate. Any excess unreacted precursor is pumped out of the reaction chamber. A second precursor is then passed over the substrate and reacts with the first precursor, forming a monolayer of film on the substrate surface. This cycle is repeated to create a film of desired thickness. In some embodiments, the plurality of assistance layers 701 may be formed of, for example, aluminum oxide, hafnium oxide, zirconium oxide, titanium oxide, titanium nitride, tungsten nitride, silicon nitride, or silicon oxide.

In some embodiments, when the plurality of assistance layers 701 are formed of aluminum oxide, the first precursor of the atomic layer deposition may be trimethylaluminum and a second precursor of the atomic layer deposition may be water or ozone.

In some embodiments, when the plurality of assistance layers 701 are formed of hafnium oxide, the first precursor of the atomic layer deposition may be hafnium tetrachloride, hafnium tert-butoxide, hafnium dimethylamide, hafnium ethylmethylamide, hafnium diethylamide, or hafnium methoxy-t-butoxide and the second precursor of the atomic layer deposition may be water or ozone.

In some embodiments, when the plurality of assistance layers 701 are formed of zirconium oxide, the first precursor of the atomic layer deposition method may be zirconium tetrachloride and the second precursor of the atomic layer deposition may be water or ozone.

In some embodiments, when the plurality of assistance layers 701 are formed of titanium oxide, the first precursor of the atomic layer deposition may be titanium tetrachloride, tetraethyl titanate, or titanium isopropoxide and the second precursor of the atomic layer deposition may be water or ozone.

In some embodiments, when the plurality of assistance layers 701 are formed of titanium nitride, the first precursor of the atomic layer deposition may be titanium tetrachloride and ammonia.

In some embodiments, when the plurality of assistance layers 701 are formed of tungsten nitride, the first precursor of the atomic layer deposition may be tungsten hexafluoride and ammonia.

In some embodiments, when the plurality of assistance layers 701 are formed of silicon nitride, the first precursor of the atomic layer deposition may be silylene, chlorine, ammonia, and/or dinitrogen tetrahydride.

In some embodiments, when the plurality of assistance layers 701 are formed of silicon oxide, the first precursor of the atomic layer deposition may be silicon tetraisocyanate or CH₃OSi(NCO)₃ and the second precursor of the atomic layer deposition may be hydrogen or ozone.

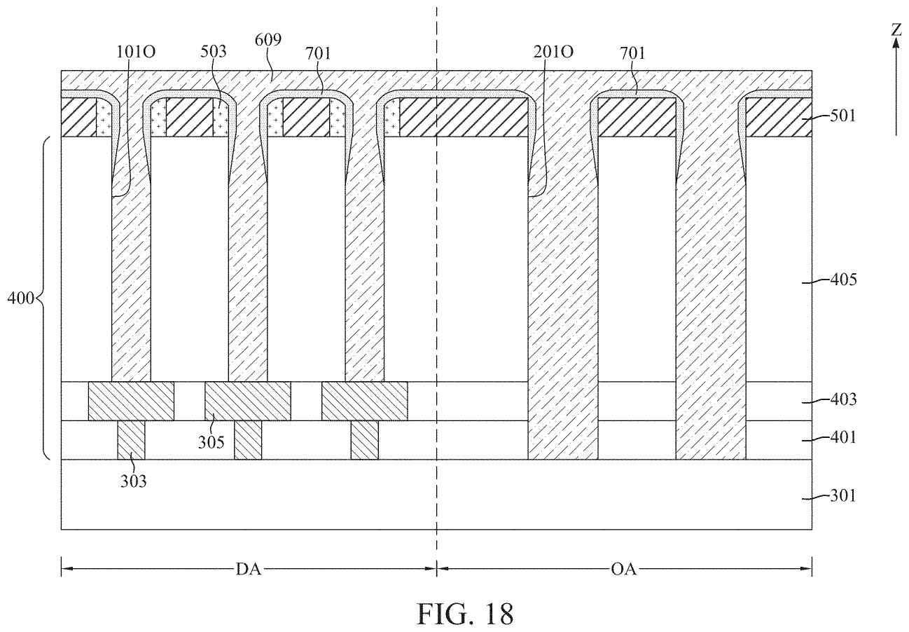

With reference to FIG. 18, the layer of conductive material 609 may be formed with a procedure similar to that illustrated in FIG. 15, and descriptions thereof are not repeated herein.

Due to the presence of the plurality of assistance layers 701, the deposition rate on the upper portions of the sidewalls of the plurality of first contact openings 101O and the plurality of second contact openings 201O may be reduced during the formation of the plurality of first contacts 101 and the plurality of second contacts 201. Hence, during the formation of the layer of conductive material 609, the deposition rate on the upper portions of the sidewalls of the plurality of first contact openings 101O and the plurality of second contact openings 201O and the deposition rate on the bottoms of the plurality of first contact openings 101O and the plurality of second contact openings 201O may become close to each other. As a result, the plurality of first contacts 101 and the plurality of second contacts 201 may be filled without any void formation. The yield of the semiconductor device 1B may be improved.

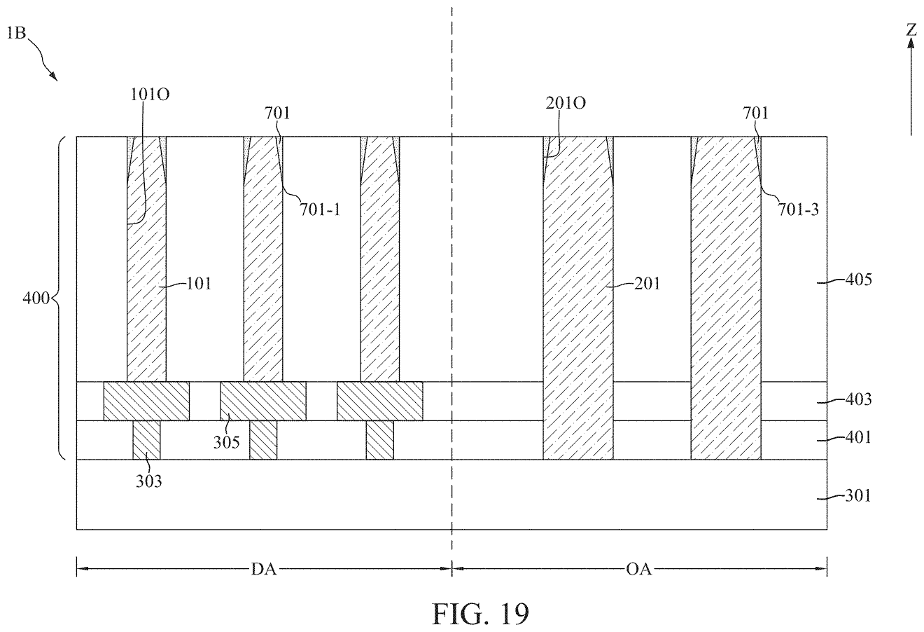

With reference to FIG. 19, a planarization process may be performed with a procedure similar to that illustrated in FIG. 16, and descriptions thereof are not repeated herein. In some embodiments, the bottommost points 701-1 of the plurality of assistance layers 701 formed above the dense area DA and the bottommost points 701-3 of the plurality of assistance layers 701 formed above the open area OA may be at a substantially same vertical level. In some embodiments, the bottommost points 701-1 of the plurality of assistance layers 701 formed above the dense area DA may be at a vertical level lower than the vertical level of the bottommost points 701-3 of the plurality of assistance layers 701 formed above the open area OA.

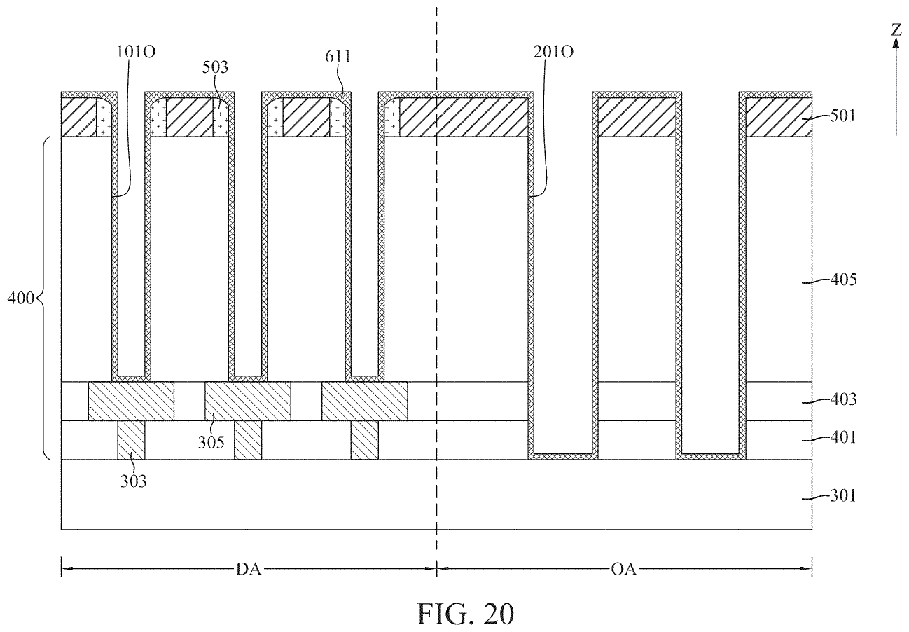

FIGS. 20 to 22 are schematic cross-sectional view diagrams illustrating part of a flow for fabricating a semiconductor device 1C in accordance with another embodiment of the present disclosure.

With reference to FIG. 20, an intermediate semiconductor device may be fabricated with a procedure similar to that illustrated in FIGS. 2 to 14, and descriptions thereof are not repeated herein. A layer of barrier material 611 may be conformally formed on the first hard mask layer 501, on the plurality of spacers 503, in the plurality of first contact openings 101O, and in the plurality of second contact openings 201O. The barrier material 611 may be, for example, titanium, titanium nitride, titanium silicon nitride, tantalum, tantalum nitride, tantalum silicon nitride, or combination thereof. In some embodiments, the thickness of the layer of barrier material 611 may be between about 10 angstroms and about 15 angstroms. In some embodiments, the layer of barrier material 611 may have a thickness between about 11 angstroms and about 13 angstroms. The layer of barrier material 611 may serve as a protective layer for its underlying structure during formation of the plurality of first contacts 101 and the plurality of second contacts 201. The layer of barrier material 611 may also serve as an adhesive layer between the dielectric structure 400 and the plurality of first contacts 101 and the plurality of second contacts 201.

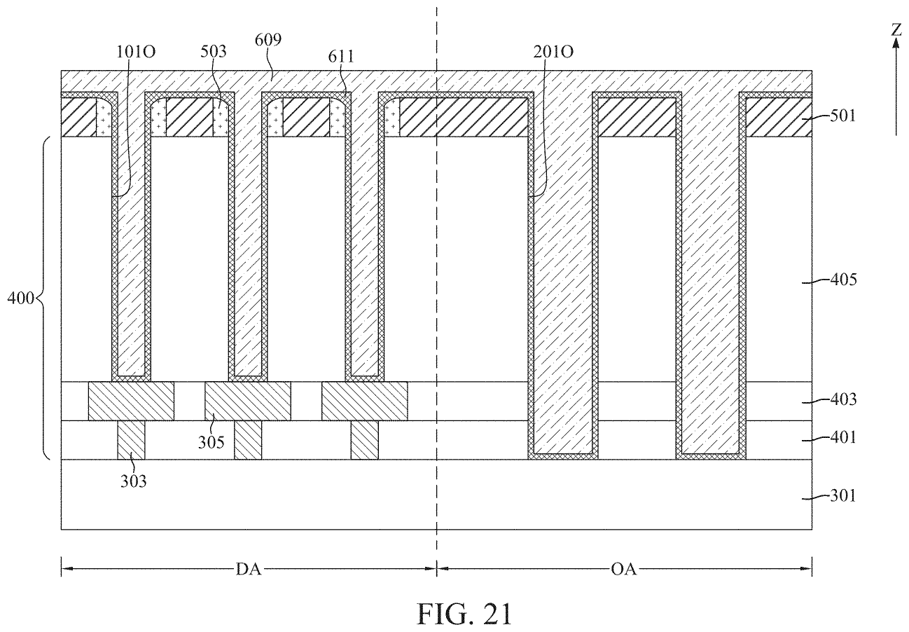

With reference to FIG. 21, the layer of conductive material 609 may completely fill the plurality of first contact openings 101O and the plurality of second contact openings 201O with a procedure similar to that illustrated in FIG. 15, and descriptions thereof are not repeated herein.

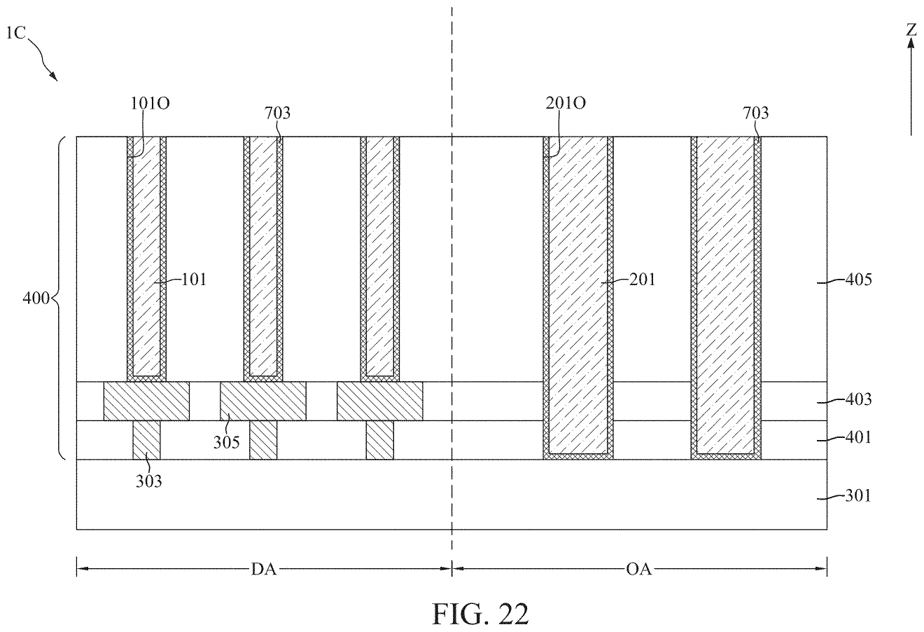

With reference to FIG. 22, a planarization process may be performed with a procedure similar to that illustrated in FIG. 16, and descriptions thereof are not repeated herein.

Due to the design of employing the spacers 503 in the etch process for the dense area DA in the fabrication of the semiconductor device of the present disclosure, the dimension of the first contacts 101 may be easily reduced so as to meet the tighter design rule of the dense area DA. Furthermore, the process complexity of fabrication of the semiconductor device 1A may be reduced as comparing to using smaller dimension of photolithography mask which may suffer serious shifting issues. In addition, the dimension of the second contact 201 for the looser design rule of the open area OA may be concurrently met by using the open area process. As a result, the yield of the semiconductor device 1A may be accordingly improved.

One aspect of the present disclosure provides a semiconductor device including a substrate including a dense area and an open area; a dielectric structure positioned on the substrate; a landing pad positioned in the dielectric structure and above the dense area; a first contact positioned on the landing pad and in the dielectric structure; and a second contact positioned in the dielectric structure and on the open area of the substrate. A top surface of the first contact and a top surface of the second contact are substantially coplanar. A width of the first contact is less than the one half of a width of the second contact.

Another aspect of the present disclosure provides a method for fabricating a semiconductor device including providing a substrate including a dense area and an open area; forming a dielectric structure on the substrate and forming a first hard mask layer on the dielectric structure; patterning the first hard mask layer to form a first mask opening above the dense area and a second mask opening above the open area; covering the open area with a first mask layer; forming a plurality of spacers on sidewalls of the first mask opening; performing a dense area etch process using the plurality of spacers and the first mask opening as pattern guides to form a first contact opening; removing the first mask layer and covering the dense area with a second mask layer; performing an open area etch process using the second mask opening as a pattern guide to form a second contact opening; and forming first contact in the first contact opening and a second contact in the second contact opening.

It should be noted that, in the description of the present disclosure, the terms “forming,” “formed” and “form” may mean and include any method of creating, building, patterning, implanting, or depositing an element, a dopant or a material. Examples of forming methods may include, but are not limited to, atomic layer deposition, chemical vapor deposition, physical vapor deposition, sputtering, co-sputtering, spin coating, diffusing, depositing, growing, implantation, photolithography, dry etching, and wet etching.

It should be noted that, in the description of the present disclosure, the functions or steps noted herein may occur in an order different from the order noted in the figures. For example, two figures shown in succession may in fact be executed substantially concurrently or may sometimes be executed in a reversed order, depending upon the functionalities or steps involved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate comprising a dense area and an open area;
a dielectric structure positioned on the substrate;
a landing pad positioned in the dielectric structure and above the dense area;
a first contact positioned on the landing pad and in the dielectric structure; and
a second contact positioned in the dielectric structure and on the open area of the substrate;
wherein a top surface of the first contact and a top surface of the second contact are substantially coplanar;
wherein a width of the first contact is less than the one half of a width of the second contact.

2. The semiconductor device of claim 1, wherein a depth of first contact is greater than two thirds of a depth of the second contact.

3. The semiconductor device of claim 1, wherein a ratio of an aspect ratio of the first contact and an aspect ratio of the second contact is about 1.33:1.00.

4. A method for fabricating a semiconductor device, comprising:
providing a substrate comprising a dense area and an open area;
forming a dielectric structure on the substrate and forming a first hard mask layer on the dielectric structure;
patterning the first hard mask layer to form a first mask opening above the dense area and a second mask opening above the open area;
covering the open area with a first mask layer;
forming a plurality of spacers on sidewalls of the first mask opening;
performing a dense area etch process using the plurality of spacers and the first mask opening as pattern guides to form a first contact opening;
removing the first mask layer and covering the dense area with a second mask layer;
performing an open area etch process using the second mask opening as a pattern guide to form a second contact opening; and
forming first contact in the first contact opening and a second contact in the second contact opening.

5. The method for fabricating the semiconductor device of claim 4, wherein forming the plurality of spacers on the sidewalls of the first mask opening comprises:
conformally forming a layer of spacer material on the first hard mask layer, on the first mask layer, and in the first mask opening; and
performing a spacer etch process to turn the layer of spacer material into the plurality of spacers.

6. The method for fabricating the semiconductor device of claim 5, wherein the spacer material comprises low temperature silicon.

7. The method for fabricating the semiconductor device of claim 5, wherein the first hard mask layer comprises polycrystalline silicon.

8. The method for fabricating the semiconductor device of claim 5, wherein a width of the first contact opening is less than one half of a width of the second contact opening.

9. The method for fabricating the semiconductor device of claim 5, further comprising forming a landing pad in the dielectric structure and above the dense area;
wherein a top surface of the landing pad is partially exposed through the first contact opening.

10. The method for fabricating the semiconductor device of claim 9, wherein a depth of the first contact opening is greater than two thirds of a depth of the second contact opening.

11. The method for fabricating the semiconductor device of claim 9, wherein an aspect ratio of the first contact opening is greater than an aspect ratio of the second contact opening.

12. The method for fabricating the semiconductor device of claim 9, wherein a ratio of an aspect ratio of the first contact opening and an aspect ratio of the second contact opening is about 1.33:1.00.

13. The method for fabricating the semiconductor device of claim 9, wherein an oxygen concentration of the dense area etch process is greater than an oxygen concentration of the open area etch process.

14. The method for fabricating the semiconductor device of claim 9, wherein a bias power of the dense area etch process is greater than a bias power of the open area etch process.

15. The method for fabricating the semiconductor device of claim 9, wherein a process pressure of the dense area etch process is less than a process pressure of the open area etch process.

16. The method for fabricating the semiconductor device of claim 9, wherein a width of the first mask opening and a width of the second mask opening are substantially the same.

17. The method for fabricating the semiconductor device of claim 9, wherein a thickness of the plurality of spacers is greater than or equal to one fourth of a width of the second contact opening.

18. The method for fabricating the semiconductor device of claim 9, wherein forming the first contact in the first contact opening and forming the second contact in the second contact opening comprising:
forming a layer of conductive material to completely fill the first contact opening and the second contact opening; and
performing a planarization process until a top surface of the dielectric structure is exposed to turn the layer of conductive material into the first contact and the second contact.

19. The method for fabricating the semiconductor device of claim 9, wherein the dense area and the open area are adjacent to each other.

20. The method for fabricating the semiconductor device of claim 9, wherein a top surface of the substrate is partially exposed through the second contact opening.
